(19) United States
(12) Patent Application Publication
(10) Pub. No.: US 2026/0333741 A1
(43) Pub. Date: Oct. 22, 2026

(54) STRUCTURE AND FORMATION METHOD OF SEMICONDUCTOR DEVICE WITH SEMICONDUCTOR NANOSTRUCTURES

(71) Applicant: Taiwan Semiconductor Manufacturing Company, Ltd., Hsinchu (TW)

(72) Inventors: Hong-Chih CHEN, Changhua County (TW); Ming-Che CHEN, Hsinchu City (TW); Ta-Chun LIN, Hsinchu (TW); Jhon-Jhy LIAW, Zhudong Township (TW)

(73) Assignee: Taiwan Semiconductor Manufacturing Company, Ltd., Hsinchu (TW)

(21) Appl. No.: 19/186,068

(22) Filed: Apr. 22, 2025

(51) Int. Cl. H10D 30/00; H10D 30/01

(52) U.S. Cl. CPC H10D 30/503; H10D 30/0193

(57) ABSTRACT

A semiconductor device structure and a formation method are provided. The method includes forming a fin structure over a substrate and forming an isolation structure surrounding a lower portion of the fin structure. The method also includes forming a cap layer extending along a sidewall and a top of the fin structure and forming a mask layer over the cap layer and the isolation structure. The method further includes partially removing the mask layer to partially expose the cap layer. A remaining portion of the mask layer forms a protective element over the isolation structure. In addition, the method includes partially removing the cap layer, and a remaining portion of the cap layer forms a protruding element between the sidewall of the fin structure and the protective element.

### BACKGROUND

The semiconductor integrated circuit (IC) industry has experienced rapid growth. Technological advances in IC materials and design have produced generations of ICs. Each generation has smaller and more complex circuits than the previous generation.

Over the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, these advances have increased the complexity of processing and manufacturing ICs. Since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1B are top views of various stages of a process for forming a portion of a semiconductor device structure, in accordance with some embodiments.

FIGS. 2A-2Q are cross-sectional views of various stages of a process for forming a portion of a semiconductor device structure, in accordance with some embodiments.

FIGS. 3A-3N are cross-sectional views of various stages of a process for forming a portion of a semiconductor device structure, in accordance with some embodiments.

FIG. 4 is a cross-sectional view of an intermediate stage of a process for forming a portion of a semiconductor device structure, in accordance with some embodiments.

FIG. 5 is a cross-sectional view of an intermediate stage of a process for forming a portion of a semiconductor device structure, in accordance with some embodiments.

FIG. 6 is a cross-sectional view of an intermediate stage of a process for forming a portion of a semiconductor device structure, in accordance with some embodiments.

FIGS. 7A-7B are cross-sectional views of various stages of a process for forming a portion of a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the disclosure may relate to FinFET structure having fins. The fins may be patterned using any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. However, the fins may be formed using one or more other applicable processes.

Embodiments of the disclosure may relate to the gate all around (GAA) transistor structures. The GAA structure may be patterned using any suitable method. For example, the structures may be patterned using one or more photolithography processes, including double-patterning or multi-patterning processes. In some embodiments, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

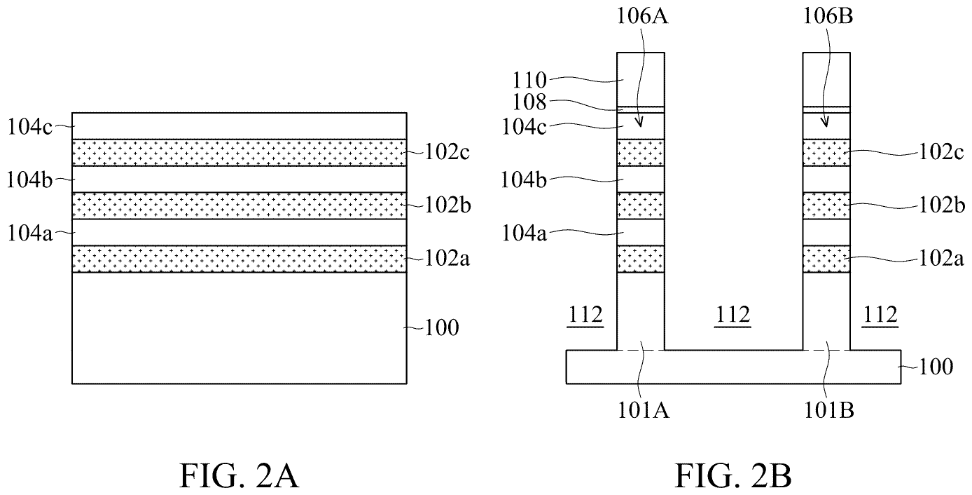

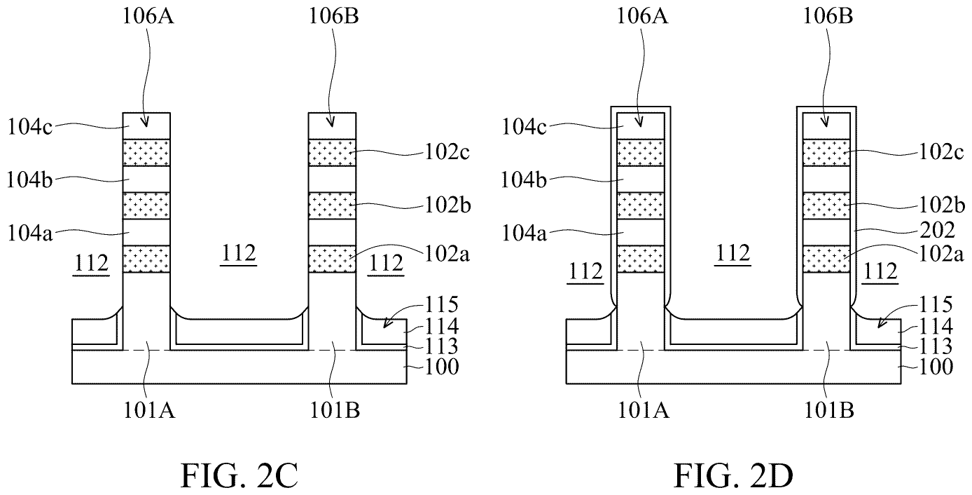

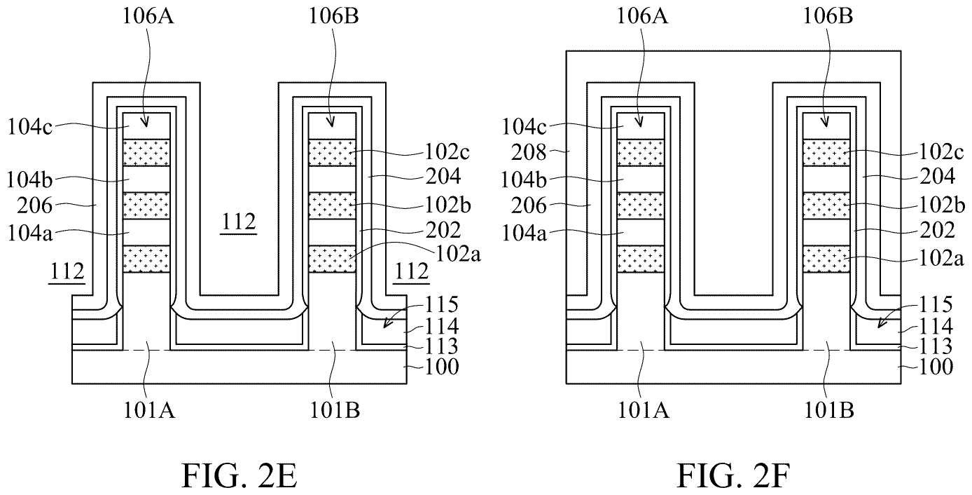

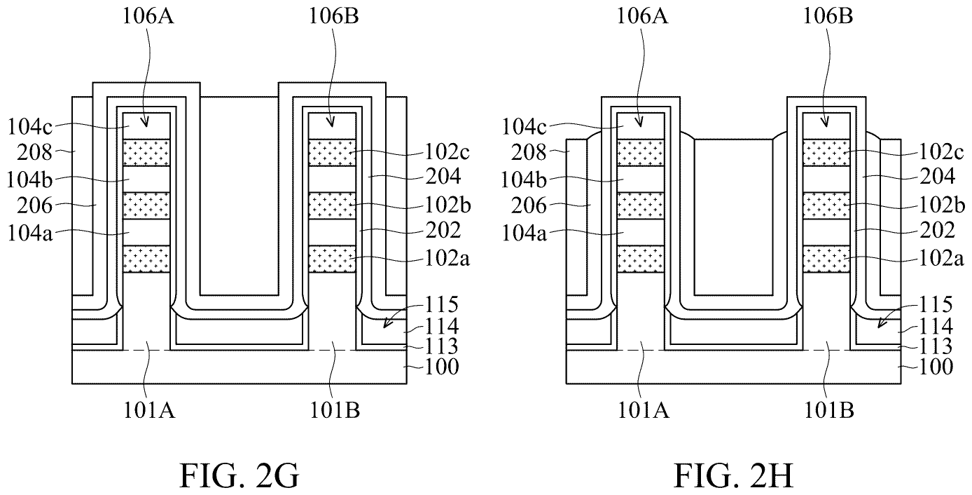

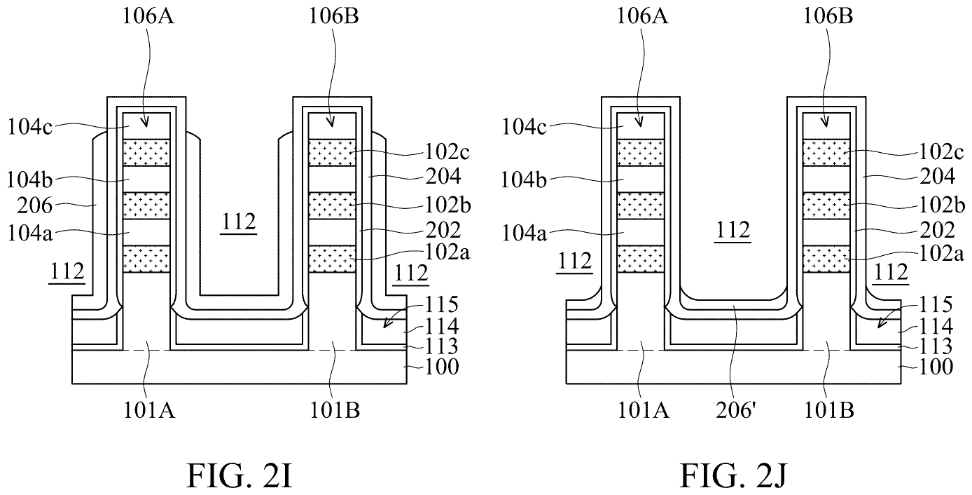

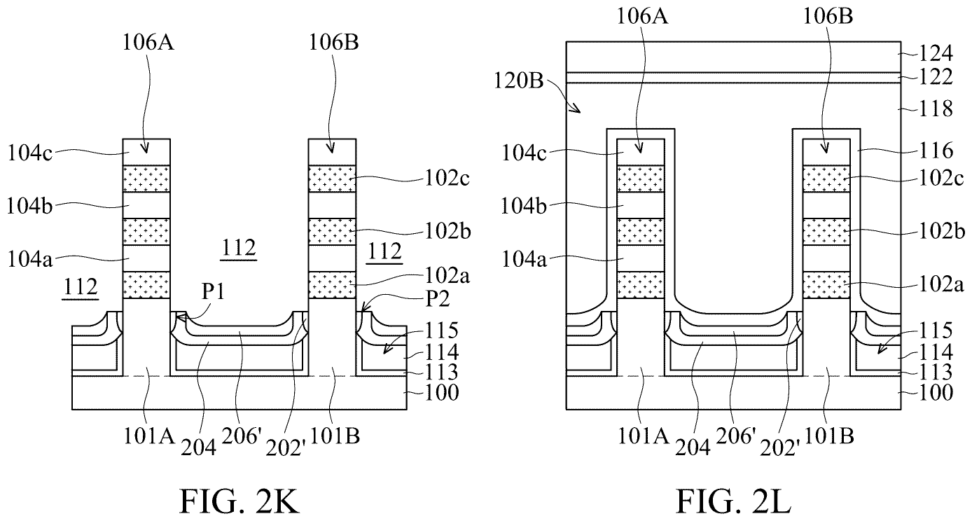

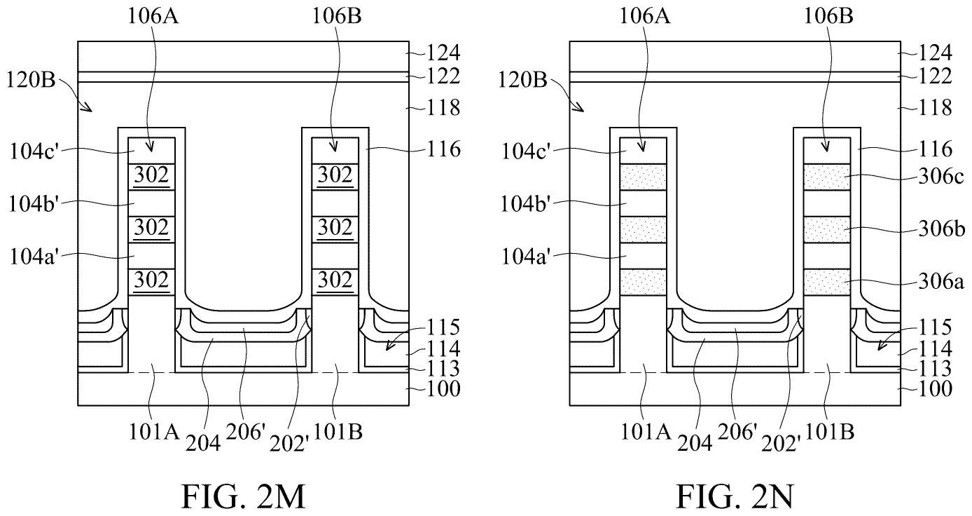

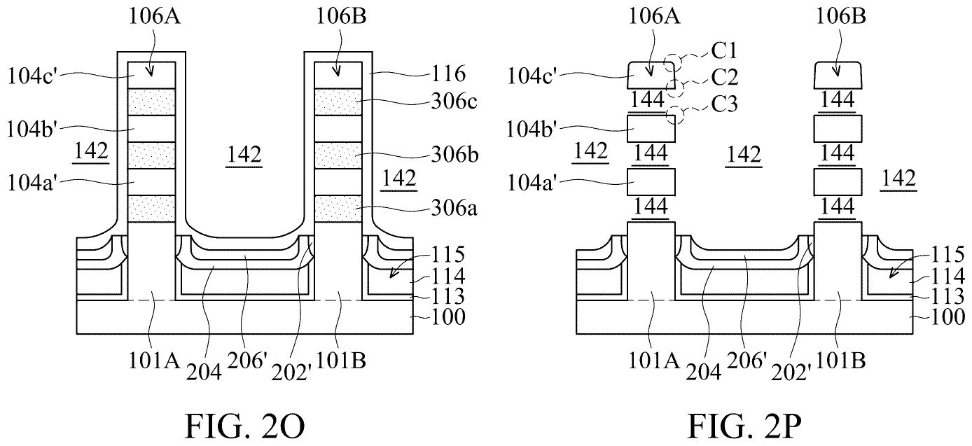

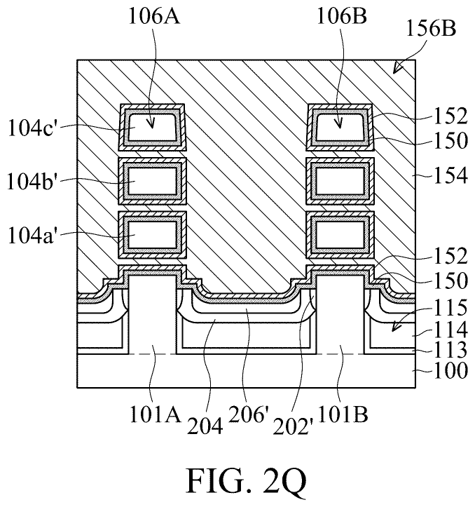

FIGS. 2A-2Q are cross-sectional views of various stages of a process for forming a portion of a semiconductor device structure, in accordance with some embodiments. As shown in FIG. 2A, a semiconductor substrate 100 is received or provided. In some embodiments, the semiconductor substrate 100 is a bulk semiconductor substrate, such as a semiconductor wafer. The semiconductor substrate 100 may include silicon or other elementary semiconductor materials such as germanium. The semiconductor substrate 100 may be un-doped or doped (e.g., p-type, n-type, or a combination thereof). In some embodiments, the semiconductor substrate 100 includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate 100 includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

In some embodiments, the semiconductor substrate 100 is an active layer of a semiconductor-on-insulator (SOI) substrate. The SOI substrate may be fabricated using a separation by implantation of oxygen (SIMOX) process, a wafer bonding process, another applicable method, or a combination thereof. In some other embodiments, the semiconductor substrate 100 includes a multi-layered structure. For example, the semiconductor substrate 100 includes a silicon-germanium layer formed on a bulk silicon layer.

As shown in FIG. 2A, a semiconductor stack having multiple semiconductor layers is formed over the semiconductor substrate 100, in accordance with some embodiments. In some embodiments, the semiconductor stack includes multiple semiconductor layers 102a, 102b, and 102c. The semiconductor stack also includes multiple semiconductor layers 104a, 104b, and 104c. In some embodiments, the semiconductor layers 102a-102c and the semiconductor layers 104a-104c are laid out in an alternating manner, as shown in FIG. 2A.

In some embodiments, the semiconductor layers 102a-102c function as sacrificial layers that will be removed in a subsequent process to release the semiconductor layers 104a-104c. The semiconductor layers 104a-104c that are released form multiple semiconductor nanostructures, which may serve as the channel structures of one or more transistors.

In some embodiments, the semiconductor layers 104a-104c that will be used to form channel structures are made of a material that is different than that of the semiconductor layers 102a-102c. In some embodiments, the semiconductor layers 104a-104c are made of or include silicon, another suitable material, or a combination thereof. In some embodiments, the semiconductor layers 102a-102c are made of or include silicon germanium. Due to the different compositions, different etching selectivity and/or different oxidation rates during subsequent processing may be achieved between the semiconductor layers 102a-102c and the semiconductor layers 104a-104c.

The present disclosure contemplates that the semiconductor layers 102a-102c and the semiconductor layers 104a-104c include any combination of semiconductor materials that can provide desired etching selectivity, desired oxidation rate differences, and/or desired performance characteristics (e.g., materials that maximize current flow).

In some embodiments, the semiconductor layers 102a-102c and 104a-104c are formed using multiple epitaxial growth operations. Each of the semiconductor layers 102a-102c and 104a-104c may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, one or more other applicable processes, or a combination thereof.

In some embodiments, the semiconductor layers 102a-102c and 104a-104c are grown in-situ in the same process chamber. In some embodiments, the growth of the semiconductor layers 102a-102c and 104a-104c are alternately and sequentially performed in the same process chamber to complete the formation of the semiconductor stack. In some embodiments, the vacuum of the process chamber is not broken before the epitaxial growth of the semiconductor stack is accomplished.

Afterwards, hard mask elements are formed over the semiconductor stack to assist in a subsequent patterning of the semiconductor stack. Each of the hard mask elements may include a first mask layer 108 and a second mask layer 110. The first mask layer 108 and the second mask layer 110 may be made of different materials. One or more photolithography processes and one or more etching processes are used to pattern the semiconductor stack into multiple fin structures. The fin structures may be patterned by any suitable method. For example, the fin structures may be patterned using one or more photolithography processes, including double-patterning or multi-patterning processes. Double-patterning or multi-patterning processes may combine photolithography and self-aligned processes, allowing patterns to be created that have, for example, pitches smaller than what is otherwise obtainable using a single, direct photolithography process.

The semiconductor stack is partially removed to form multiple fin structures (including fin structures 106A and 106B) and multiple trenches 112, as shown in FIG. 2B in accordance with some embodiments. Each of the fin structures 106A-106B may include portions of the semiconductor layers 102a-102c and 104a-104c and multiple semiconductor fins (including semiconductor fins 101A and 101B), as shown in FIG. 2B. The semiconductor substrate 100 may also be partially removed during the etching process that forms the fin structures. Protruding portions of the semiconductor substrate 100 that remain form the semiconductor fins 101A and 101B.

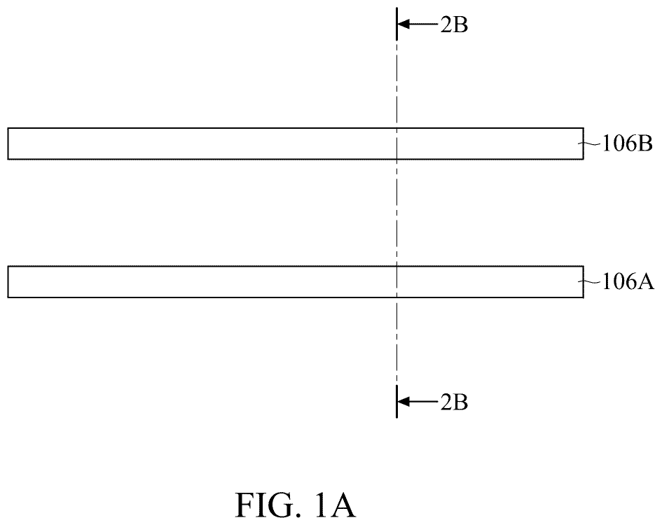

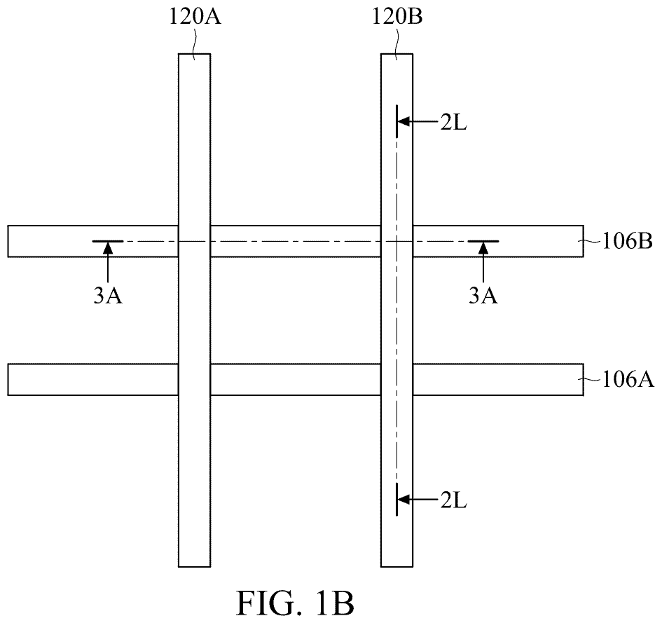

FIGS. 1A-1B are top views of various stages of a process for forming a portion of a semiconductor device structure, in accordance with some embodiments. As shown in FIG. 1A, multiple fin structures 106A and 106B are formed, in accordance with some embodiments. In some embodiments, the fin structures 106A and 106B are oriented lengthwise. In some embodiments, the fin structures 106A and 106B are oriented in directions that are substantially parallel to each other, as shown in FIG. 1A. In some embodiments, FIG. 2B is a cross-sectional view of the structure taken along the line 2B-2B in FIG. 1A.

Afterwards, as shown in FIG. 2C, an isolation structure 115 is formed to surround lower portions of the fin structures 106A and 106B, in accordance with some embodiments. In some embodiments, the isolation structure 115 includes dielectric fillings 114 and a liner layer 113 that is adjacent to the semiconductor fins 101A and 101B.

In some embodiments, a liner layer 113 and one or more dielectric layers for forming the dielectric fillings 114 are sequentially deposited over the fin structures 106A and 106B and the semiconductor substrate 100. The dielectric layers may include one or more oxide-based material. The dielectric layers may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, one or more other suitable materials, or a combination thereof. The liner layer 113 may be made of or include silicon nitride, silicon oxynitride, silicon carbide, silicon oxycarbide, one or more other suitable materials, or a combination thereof. The liner layer 113 and the dielectric layers and the may be deposited using a flowable chemical vapor deposition (FCVD) process, an atomic layer deposition (ALD) process, a chemical vapor deposition (CVD) process, one or more other applicable processes, or a combination thereof.

Afterwards, a planarization process is used to partially remove the dielectric layers and the liner layer 113. The hard mask elements (including the first mask layer 108 and the second mask layer 110) may also function as a stop layer of the planarization process. The planarization process may include a chemical mechanical polishing (CMP) process, a grinding process, a dry polishing process, an etching process, one or more other applicable processes, or a combination thereof.

Afterwards, one or more etching back processes are used to partially remove the dielectric layers and the liner layer 113. As a result, the remaining portion of the dielectric layers forms the dielectric fillings 114 of the isolation structure 115. Upper portions of the fin structures 106A and 106B protrude from the top surface of the isolation structure 115, as shown in FIG. 2C.

In some embodiments, the etching back process for forming the isolation structure 115 is carefully controlled to ensure that the topmost surface of the isolation structure 115 is positioned at a suitable height level, as shown in FIG. 2C. In some embodiments, the topmost surface of the isolation structure 115 is below the bottommost surface of the semiconductor layer 102a that functions as a sacrificial layer. The side edges of the bottommost sacrificial layer (i.e., the semiconductor layer 102a) are thus exposed without being covered by the isolation structure 115, thereby facilitating the subsequent removal process of the semiconductor layers 102a-102c.

In some embodiments, the top surface of the isolation structure 115 is non-planar, as shown in FIG. 2C. In some embodiments, the isolation structure has a first portion and a second portion. The first portion is beside the semiconductor fin 101A. The first portion is between the second portion and the semiconductor fin 101A, and the first portion is thicker than the second portion. In some embodiments, the isolation structure 115 gradually becomes thinner along a direction away from the semiconductor fin 101A.

Afterwards, the hard mask elements (including the first mask layer 108 and the second mask layer 110) are removed. Alternatively, in some other embodiments, the hard mask elements are removed or consumed during the planarization process and/or the etching back process that forms the isolation structure 115.

As shown in FIG. 2D, a cap layer 202 is formed over the fin structures 106A and 106B, in accordance with some embodiments. The cap layer 202 may extend along the sidewalls and tops of the fin structures 106A and 106B. The cap layer 202 may be made of or include silicon, silicon nitride, carbon-containing silicon nitride, silicon carbide, silicon oxynitride, carbon-containing silicon oxynitride, silicon oxide, another suitable material, or a combination thereof.

In some embodiments, the cap layer 202 is a semiconductor layer that is epitaxially grown on the exposed surfaces of the fin structures 106A and 106B. For example, the cap layer 202 is a silicon cap layer that is selectively grown on the fin structures 106A and 106B that have semiconductor surfaces. In some embodiments, the lower portion of the cap layer 202 that is next to the isolation structure 115 may be thinner than other portions of the cap layer 202. The cap layer 202 may protect the fin structures 106A and 106B from being oxidized or damaged during subsequent processes. The diffusion of germanium from the semiconductor layers 102a-102c to the semiconductor layers 104a-104c may be minimized due to the cap layer 202.

As shown in FIG. 2E, a liner layer 204 is deposited over the cap layer 202 and the isolation structure 115, in accordance with some embodiments. The liner layer 204 may be made of or include silicon oxide, silicon oxynitride, carbon-containing silicon oxide, carbon-containing silicon oxynitride, another suitable material, or a combination thereof. The liner layer 204 may be deposited using a CVD process, an ALD process, another applicable process, or a combination thereof.

Afterwards, a mask layer 206 is deposited over the liner layer 204, as shown in FIG. 2E in accordance with some embodiments. The mask layer 206 may be made of or include silicon nitride, silicon oxynitride, carbon-containing silicon nitride, carbon-containing silicon oxynitride, another suitable material, or a combination thereof. The mask layer 206 may be deposited using a CVD process, an ALD process, another applicable process, or a combination thereof.

As shown in FIG. 2F, an anti-reflection layer 208 is formed over the mask layer 206, in accordance with some embodiments. The anti-reflection layer 208 may overfill the trenches 112 between the fin structures 106A and 106B. The anti-reflection layer 208 may include an organic anti-reflection coating, an inorganic anti-reflection coating, or a combination thereof.

As shown in FIG. 2G, the anti-reflection layer 208 is recessed such that the upper portions of the mask layer 206 previously covered by the anti-reflection layer 208 are exposed, in accordance with some embodiments. One or more etching processes may be used to partially remove the anti-reflection layer 208 and to expose the upper portions of the mask layer 206.

As shown in FIG. 2H, the upper portions of the mask layer 206 are removed, in accordance with some embodiments. The anti-reflection layer 208 mal also be partially removed during the removal of the upper portions of the mask layer 206. One or more etching processes may be used to partially remove the mask layer 206.

Afterwards, the remaining portions of the anti-reflection layer 208 are removed, as shown in FIG. 2I in accordance with some embodiments. As a result, the mask layer 206 is exposed.

As shown in FIG. 2J, the mask layer 206 is partially removed, in accordance with some embodiments. As a result, the remaining portions of the mask layer 206 form multiple protective elements 206′ between the fin structures 106A and 106B. One or more etching processes may be used to partially remove the mask layer 206. For example, one or more isotropic etching processes are used to partially remove the mask layer 206 and to form the protective elements 206′ above the isolation structure 115. The protective elements 206′ may serve to protect the isolation structure 115 located underneath during subsequent processes.

As shown in FIG. 2K, the liner layer 204 and the cap layer 202 are partially removed, in accordance with some embodiments. One or more etching processes may be used to partially remove the liner layer 204 and the cap layer 202. As a result, the remaining portions of the cap layer 202 form protruding elements 202′, as shown in FIG. 2K. Each of the protruding elements 202′ protrudes from the sidewall of the semiconductor fin 101A or 101B nearby. In some embodiments, each of the protruding elements 202′ is positioned between the protective element 206′ and the semiconductor fin 101A or 101B nearby.

In some embodiments, one of the protruding elements 202′ has an outermost point P1, as shown in FIG. 2K. In some embodiments, the outermost point P1 is vertically between the top and bottom of the protective element 206′. In some embodiments, one of the protruding elements 202′ has an outermost point P2, as shown in FIG. 2K. In some embodiments, the outermost point P2 is substantially at the same height as the top of the protective element 206′.

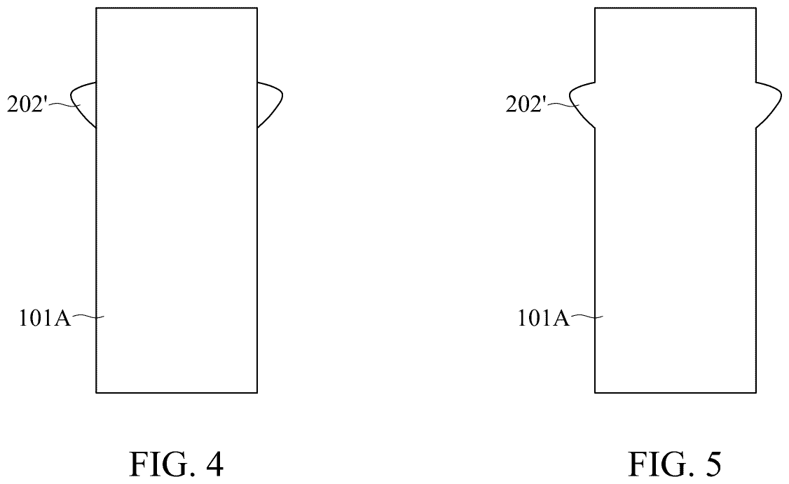

FIG. 4 is a cross-sectional view of an intermediate stage of a process for forming a portion of a semiconductor device structure, in accordance with some embodiments. The interface between the protruding elements 202′ and the semiconductor fin 101A may be observed using, for example, a transmission electron microscope (TEM).

FIG. 5 is a cross-sectional view of an intermediate stage of a process for forming a portion of a semiconductor device structure, in accordance with some embodiments. In some embodiments, the protruding elements 202′ are semiconductor materials epitaxially grown on the semiconductor fin 101A. In some embodiments, the protruding elements 202′ and the semiconductor fin 101A are made of the same material such as silicon. The interface between the protruding elements 202′ and the semiconductor fin 101A may not be clearly detectable. In some other embodiments, there is no interface between the protruding elements 202′ and the semiconductor fin 101A.

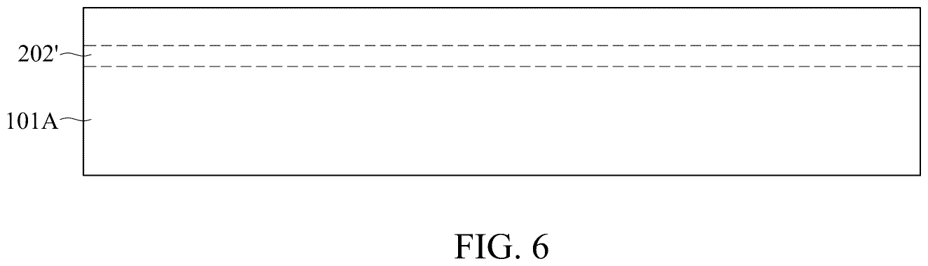

FIG. 6 is a cross-sectional view of an intermediate stage of a process for forming a portion of a semiconductor device structure, in accordance with some embodiments. In some embodiments, the cross-sectional views in FIGS. 4 and 6 may cut along planes that are perpendicular to each other. In some embodiments, each protruding element 202′ extends along the longitudinal axis of the semiconductor fin 101A, as shown in FIG. 6. In some embodiments, the protective element 206′ has a skirt-like profile.

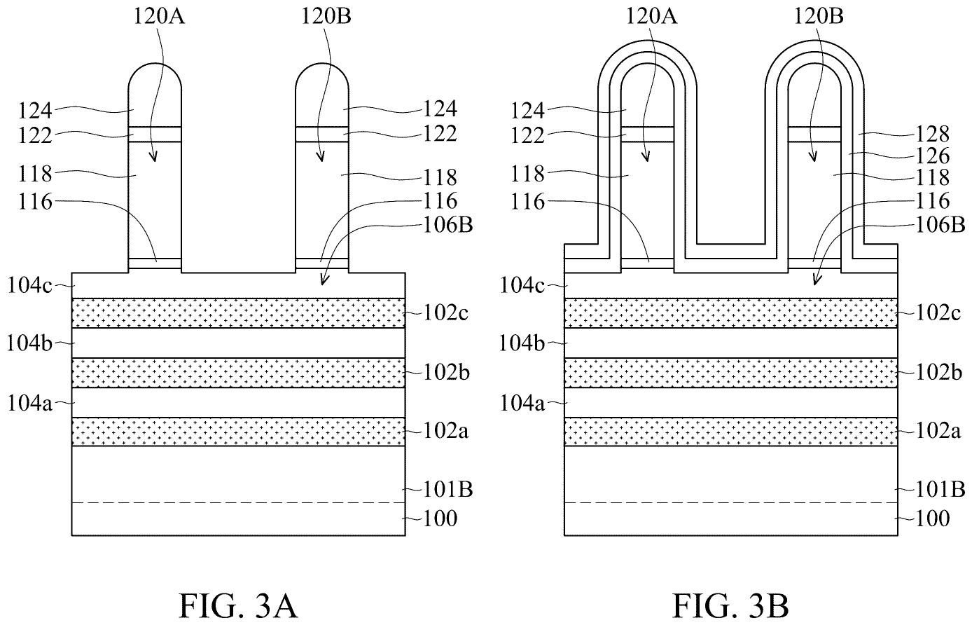

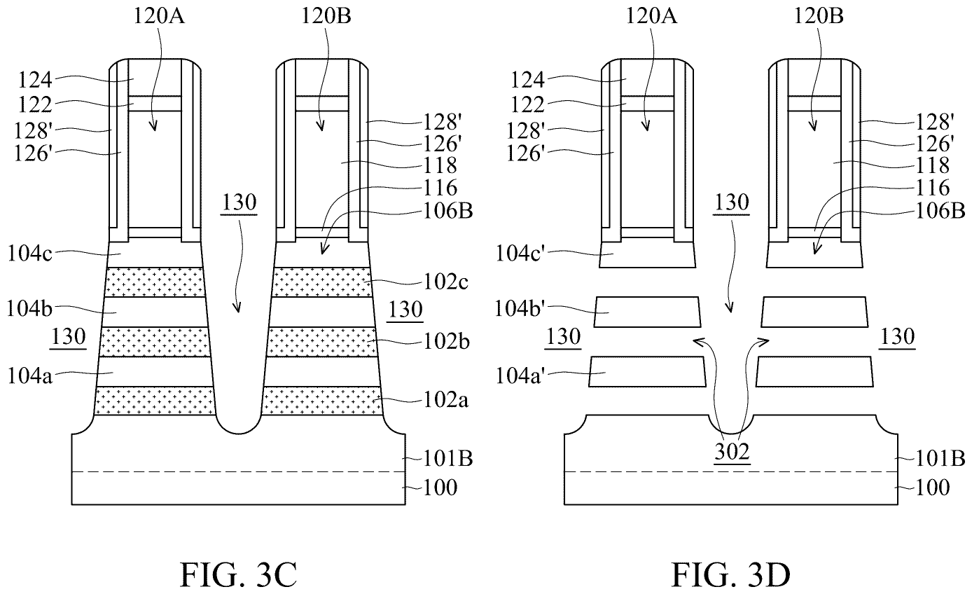

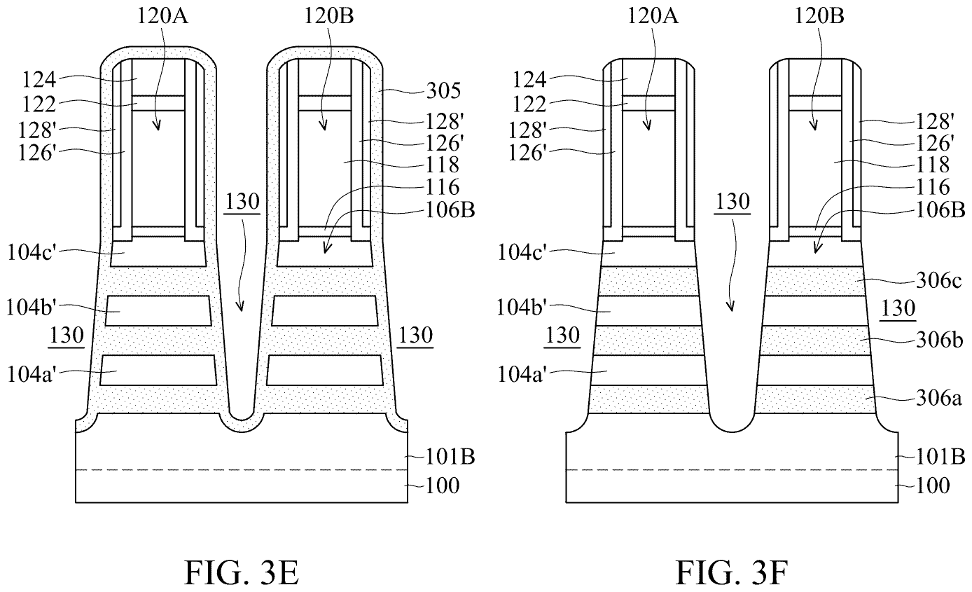

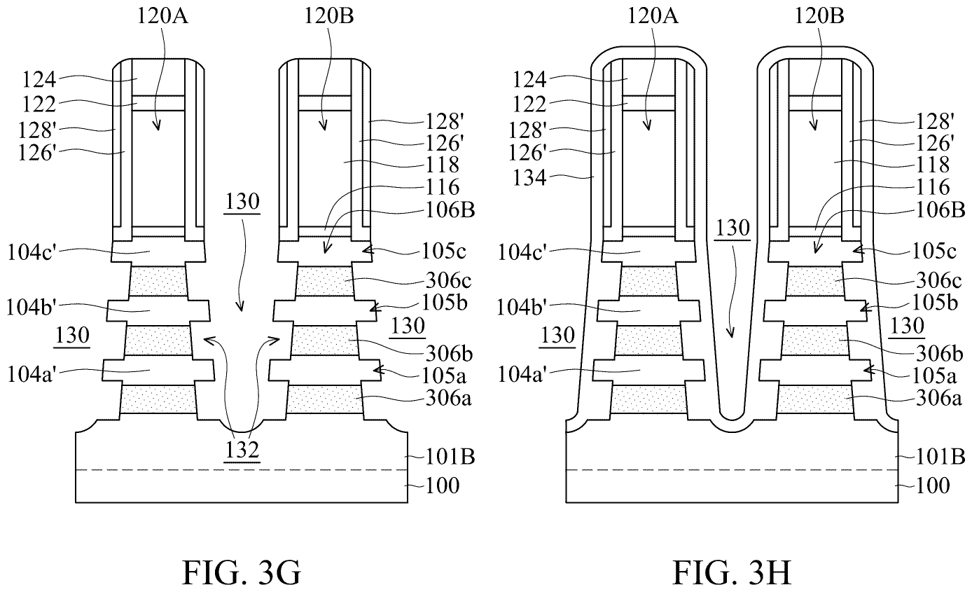

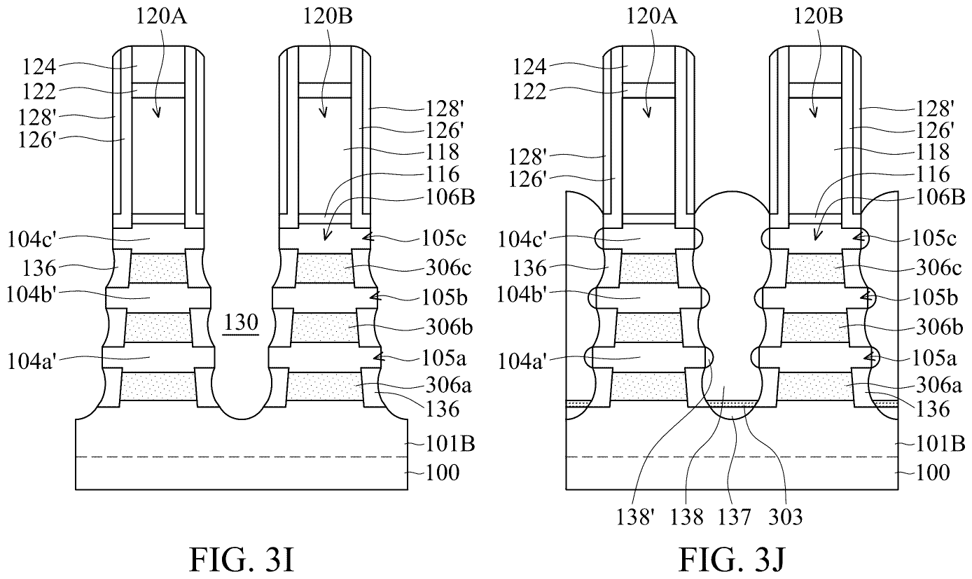

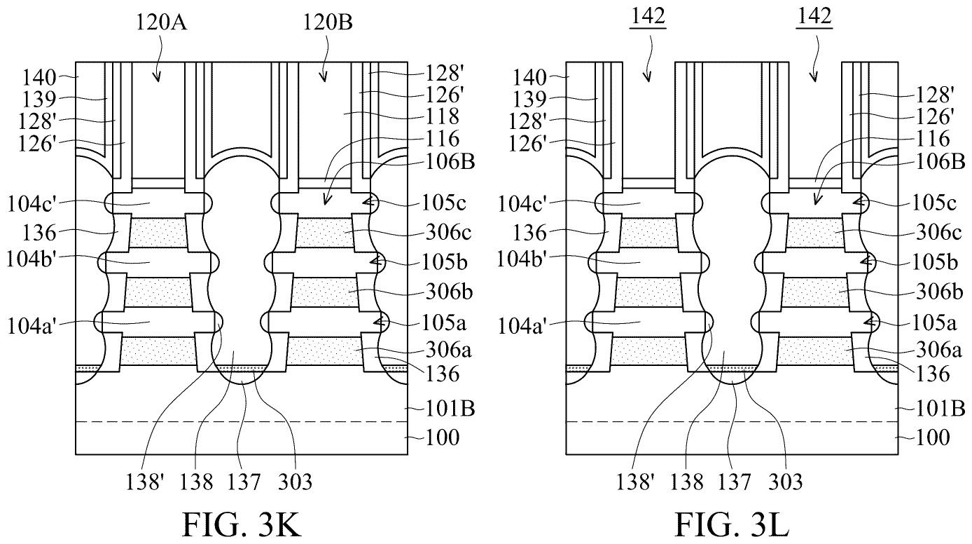

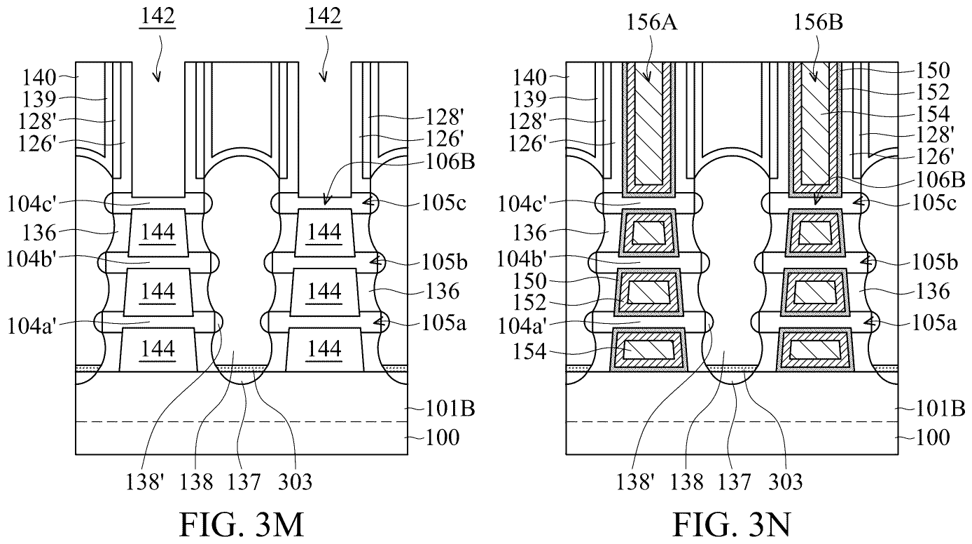

Afterwards, dummy gate stacks 120A and 120B are formed to extend across the fin structures 106A and 106B, as shown in FIG. 1B in accordance with some embodiments. In some embodiments, FIG. 2L is a cross-sectional view of the structure taken along the line 2L-2L in FIG. 1B. FIGS. 3A-3N are cross-sectional views of various stages of a process for forming portions of a semiconductor device structure, in accordance with some embodiments. In some embodiments, FIG. 3A is a cross-sectional view of the structure taken along the lines 3A-3A in FIG. 1B.

As shown in FIGS. 1B, 2L, and 3A, the dummy gate stacks 120A and 120B partially cover and extend across the fin structures 106A and 106B, in accordance with some embodiments. As shown in FIG. 2L, the dummy gate stack 120B extends across and is wrapped around the fin structures 106A and 106B. As shown in FIG. 1B, other portions of the fin structures 106A and 106B are exposed without being covered by the dummy gate stack 120A and 120B. In some embodiments, the dummy gate stacks 120A and 120B partially cover the protruding elements 202′ and the protective elements 206′. Other portions of the protruding elements 202′ and the protective elements 206′ are exposed without being covered by the dummy gate stack 120A and 120B.

As shown in FIGS. 2L and 3A, each of the dummy gate stacks 120A and 120B includes a dummy gate dielectric layer 116 and a dummy gate electrode 118. The dummy gate dielectric layer 116 may be made of or include silicon oxide or another suitable material. The dummy gate electrodes 118 may be made of or include polysilicon or another suitable material.

In some embodiments, a dummy gate dielectric material layer and a dummy gate electrode layer are sequentially deposited over the isolation structure 115 and the fin structures 106A and 106B. The dummy gate dielectric material layer may be deposited using an ALD process, a CVD process, one or more other applicable processes, or a combination thereof. The dummy gate electrode layer may be deposited using a CVD process. Afterwards, the dummy gate dielectric material layer and the dummy gate electrode layer are patterned to form the dummy gate stacks 120A and 120B.

In some embodiments, hard mask elements 122 and 124 are used to assist in the patterning process for forming the dummy gate stacks 120A and 120B. With the hard mask elements 122 and 124 as an etching mask, one or more etching processes are used to partially remove the dummy gate dielectric material layer and the dummy gate electrode layer. As a result, remaining portions of the dummy gate dielectric material layer and the dummy gate electrode layer form the dummy gate stacks 120A and 120B.

As shown in FIG. 3B, spacer layers 126 and 128 are afterwards deposited over the dummy gate stacks 120A and 120B and the fin structure 106B, in accordance with some embodiments. The spacer layers 126 and 128 extend along the tops and sidewalls of the dummy gate stacks 120A and 120B, as shown in FIG. 3B. The spacer layers 126 and 128 also extend along the top of the fin structure 106B, as shown in FIG. 3B.

In some embodiments, the spacer layers 126 and 128 are made of different materials. In some other embodiments, the spacer layers 126 and 128 are made of the same material. The spacer layers 126 and 128 may be made of or include silicon nitride, silicon carbide, silicon oxycarbide, carbon-containing silicon oxynitride, silicon oxide, another suitable material, or a combination thereof. In some embodiments, each of the spacer layers 126 and 128 is a single layer. In some other embodiments, one or both of the spacer layers 126 and 128 include multiple sub-layers. Some of the sub-layers may be made of different materials. Some of the sub-layers may be made of similar materials with different compositions. For example, one of the sub-layers may have a greater atomic concentration of carbon than other sub-layers. The spacer layers 126 and 128 may be sequentially deposited using a CVD process, an ALD process, a physical vapor deposition (PVD) process, another applicable process, or a combination thereof.

As shown in FIG. 3C, the spacer layers 126 and 128 are partially removed, in accordance with some embodiments. One or more anisotropic etching processes may be used to partially remove the spacer layers 126 and 128. As a result, remaining portions of the spacer layers 126 and 128 form gate spacers 126′ and 128′, respectively. The gate spacers 126′ and 128′ extend along the sidewalls of the dummy gate stacks 120A and 120B, as shown in FIG. 3C.

Afterwards, the fin structures 106A and 106B are partially removed to form recesses used for containing subsequently formed epitaxial structures. As shown in FIG. 3C, the fin structure 106B is partially removed to form recesses 130, in accordance with some embodiments. The recesses 130 expose the side edges of the semiconductor layers 104a-104c on which epitaxial structures (such as source/drain structures) will subsequently be formed. A source/drain structure may refer to a source structure or a drain structure, individually or collectively, depending upon the context.

One or more etching processes may be used to form the recesses 130. In some embodiments, a dry etching process is used to form the recesses 130. Alternatively, a wet etching process may be used to form the recesses 130. In some embodiments, each of the recesses 130 penetrates into the fin structure 106B. In some embodiments, the recesses 130 further extend into the semiconductor fin 101B, as shown in FIG. 3C. In some embodiments, the gate spacers 126′ and 128′ and the recesses 130 are simultaneously formed using the same etching process.

In some embodiments, each of the recesses 130 has slanted sidewalls. Upper portions of the recesses 130 are larger (or wider) than lower portions of the recesses 130. In these cases, due to the profile of the recesses 130, an upper semiconductor layer (such as the semiconductor layer 104c) is shorter than a lower semiconductor layer (such as the semiconductor layer 104b).

However, embodiments of the disclosure have many variations. In some other embodiments, the recesses 130 have substantially vertical sidewalls. In these cases, due to the profile of the recesses 130, an upper semiconductor layer (such as the semiconductor layer 104c) is substantially as wide as a lower semiconductor layer (such as the semiconductor layer 104b).

Afterwards, the semiconductor layers 102a-102c, which serve as sacrificial layers, are removed. As a result, the structure shown in FIGS. 2M and 3D is formed, in accordance with some embodiments. One or more etching processes may be used to remove the semiconductor layers 102a-102c. After the removal of the semiconductor layers 102a-102c, multiple recesses 302 are formed, as shown in FIGS. 2M and 3D. The remaining portions of the semiconductor layers 104a-104c that are released from the semiconductor layers 102a-102c form multiple semiconductor nanostructures 104a′, 104b′, and 104c′, as shown in FIGS. 2M and 3D. With the support of the dummy gate stacks 120A and 120B, the semiconductor nanostructures 104a∝-104c′ are securely held in place.

As shown in FIG. 3E, a dielectric layer 305 is deposited to overfill the recesses 302 and to surround the semiconductor nanostructures 104a′-104c′, in accordance with some embodiments. The dielectric layer 305 may also extend over the top and sidewalls of the dummy gate stacks 120A and 120B. The dielectric layer 305 may be made of an oxide material, a nitride material, another suitable material, or a combination thereof. The dielectric layer 305 may be made of or include silicon oxide, silicon oxynitride, aluminum oxide, silicon nitride, another suitable material, or a combination thereof.

In some embodiments, the dielectric layer 305 is a single layer. In some other embodiments, the dielectric layer 305 includes multiple sub-layers. In some embodiments, the sub-layers of the dielectric layer 305 are made of the same material. In some other embodiments, some of the sub-layers of the dielectric layer 305 are made of different materials.

The dielectric layer 305 may be deposited using a CVD process, an ALD process, a flowable chemical vapor deposition (FCVD) process, another applicable process, or a combination thereof. In some embodiments, the formation of the dielectric layer 305 further involves one or more etching processes that are used to tune the profile of the deposited sub-layers of the dielectric layer 305.

As shown in FIGS. 2N and 3F, multiple dielectric nanostructures 306a, 306b, and 306c are formed in the recesses 302, in accordance with some embodiments. In some embodiments, the dielectric layer 305 is partially removed using one or more etching processes. The portion of the dielectric layer 305 outside of the recesses 302 are removed. As a result, the remaining portions of the dielectric layer 305 form multiple dielectric nanostructures 306a, 306b, and 306c, as shown in FIGS. 2N and 3F.

Afterwards, as shown in FIG. 3G, the dielectric nanostructures 306a-306c are partially removed to pull back the side edges of the dielectric nanostructures 306a-306c, in accordance with some embodiments. One or more etching processes may be used to partially remove the dielectric nanostructures 306a-306c. As a result, the side edges of the dielectric nanostructures 306a-306c retreat from the side edges of the semiconductor nanostructures 104a′-104c′. As shown in FIG. 3G, recesses 132 are formed due to the lateral etching of the dielectric nanostructures 306a-306c. The recesses 132 may be used to contain inner spacers that will be formed later.

In some embodiment, the semiconductor nanostructures 104a′-104c′ are also slightly etched during the lateral etching of the dielectric nanostructures 306a-306c. As a result, edge portions of the semiconductor nanostructures 104a′-104c′ are partially etched and thus shrink to form edge portions 105a-105c, as shown in FIG. 3G. As shown in FIG. 3G, each of the edge portions 105a-105c of the semiconductor nanostructures 104a′-104c′ is thinner than the corresponding inner portion of the semiconductor nanostructures 104a′-104c′.

Embodiments of the disclosure are not limited thereto. Many variations and/or modifications can be made to embodiments of the disclosure. In some other embodiments, the semiconductor nanostructures 104a′-104c′ are substantially not etched during the lateral etching of the dielectric nanostructures 306a-306c. As a result, edge portions 105a-105c of the semiconductor nanostructures 104a′-104c′ are substantially not shrunk. In some embodiments, each of the edge portions 105a-105c of the semiconductor nanostructures 104a′-104c′ is substantially as thick as the corresponding inner portion of the semiconductor nanostructures 104a′-104c′.

As shown in FIG. 3H, an insulating layer 134 is deposited over the structure shown in FIG. 3G, in accordance with some embodiments. The insulating layer 134 covers the dummy gate stacks 120A and 120B and fills the recesses 132. The insulating layer 134 may be made of or include carbon-containing silicon nitride (SiCN), carbon-containing silicon oxynitride (SiOCN), carbon-containing silicon oxide (SiOC), silicon oxide, silicon nitride, another suitable material, or a combination thereof.

In some embodiments, the dielectric nanostructures 306a-306c are made of silicon oxide, and the insulating layer 134 is made of carbon-containing silicon oxynitride, silicon nitride, another suitable material, or a combination thereof. In some embodiments, the dielectric nanostructures 306a-306c are made of silicon nitride, and the insulating layer 134 is made of carbon-containing silicon oxynitride, silicon oxide, another suitable material, or a combination thereof. In some embodiments, the dielectric nanostructures 306a-306c are made of silicon oxynitride, and the insulating layer 134 is made of carbon-containing silicon oxynitride, another suitable material, or a combination thereof. In some embodiments, the dielectric nanostructures 306a-306c are made of aluminum oxide, and the insulating layer 134 is made of carbon-containing silicon oxynitride, another suitable material, or a combination thereof.

In some embodiments, the insulating layer 134 is a single layer. In some other embodiments, the insulating layer 134 includes multiple sub-layers. Some of the sub-layers may be made of different materials and/or contain different compositions. The insulating layer 134 may be deposited using a CVD process, an ALD process, another applicable process, or a combination thereof.

As shown in FIG. 3I, one or more etching processes are used to partially remove the insulating layer 134, in accordance with some embodiments. The portions of the insulating layer 134 outside of the recesses 132 are removed. As a result, the remaining portions of the insulating layer 134 form inner spacers 136, as shown in FIG. 3I. The one or more etching processes may include a dry etching process, a wet etching process, or a combination thereof.

The inner spacers 136 cover the side edges of the dielectric nanostructures 306a-306c, as shown in FIG. 3I. The inner spacers 136 may be used to prevent subsequently formed epitaxial structures (which function as source/drain structures, for example) from being damaged during a subsequent process for removing the dielectric nanostructures 306a-306c. In some embodiments, the inner spacers 136 are made of a low-k material that has a lower dielectric constant than that of silicon oxide. In these cases, the inner spacers 136 may also be used to reduce parasitic capacitance between the subsequently formed source/drain structures and the gate stacks. As a result, the operation speed of the semiconductor device structure may be improved.

In some embodiments, after the etching process for forming the inner spacers 136, portions of the semiconductor fin 101B originally covered by the insulating layer 134 are exposed by the recesses 130, as shown in FIG. 3I. The side edges of the semiconductor nanostructures 104a′-104c′ are also exposed by the recesses 130, as shown in FIG. 3I.

As shown in FIG. 3J, semiconductor separation structures 137 are formed over the bottoms of the recesses 130, in accordance with some embodiments. In some embodiments, the semiconductor separation structures 137 are epitaxial structures that are undoped. In some embodiments, the semiconductor separation structures 137 are substantially free of n-type dopants or p-type dopants. The semiconductor separation structures 137 may help to reduce or prevent current leakage from epitaxial structures that will be formed. The semiconductor separation structures 137 may provide relatively planar surfaces to facilitate the subsequent formation of the epitaxial structures.

The semiconductor separation structures 137 may be made of or include silicon, silicon germanium, another suitable material, or a combination thereof. The semiconductor separation structures 137 may be formed using a selective epitaxial growth (SEG) process, a CVD process (e.g., a vapor-phase epitaxy (VPE) process, a low-pressure chemical vapor deposition (LPCVD) process, and/or an ultra-high vacuum CVD (UHV-CVD) process), a molecular beam epitaxy process, another applicable process, or a combination thereof. In some embodiments, the formation of the semiconductor separation structures 137 involve one or more etching processes that are used to fine-tune the profiles of the semiconductor separation structures 137.

Afterwards, bottom isolation elements 303 are selectively formed on the semiconductor separation structures 137, as shown in FIG. 3J in accordance with some embodiments. The bottom isolation elements 303 may be used to further prevent leakage current between the semiconductor fin 101B and the epitaxial structures that will be formed on the bottom isolation elements 303.

In some embodiments, the bottom isolation elements 303 are made of or include a dielectric material. The dielectric material may include silicon oxide, silicon nitride, carbon-containing silicon nitride, carbon-containing silicon oxynitride, carbon-containing silicon oxide, aluminum oxide, hafnium oxide, another suitable material, or a combination thereof. The formation of the bottom isolation elements 303 may involve one or more deposition processes and one or more patterning processes.

However, embodiments of the disclosure are not limited thereto. Many variations and/or modifications can be made to embodiments of the disclosure. In some other embodiments, the bottom isolation elements 303 and/or the semiconductor separation structures 137 are not formed.

Afterwards, as shown in FIG. 3J, epitaxial structures 138 are formed on the bottom isolation elements 303 and the side edges of the semiconductor nanostructures 104a′-104c′, in accordance with some embodiments. In some embodiments, the top surfaces of the epitaxial structures 138 are higher than the top surface of the dummy gate dielectric layer 116, as shown in FIG. 3J. In some other embodiments, the epitaxial structures 138 are substantially as high as the tops of the edge portions 105c.

In some embodiments, the epitaxial structures 138 connect to the semiconductor nanostructures 104a′-104c′. Each of the semiconductor nanostructures 104a′-104c′ is sandwiched between the epitaxial structures 138. In some embodiments, the epitaxial structures 138 have lightly doped portions 138′ adjacent to the semiconductor nanostructures 104a′-104c′. The dopant concentration of the lightly doped portions 138′ is lower than other portions of the epitaxial structures 138.

In some embodiments, the epitaxial structures 138 are p-type doped regions. The epitaxial structures 138 may include epitaxially grown silicon germanium (SiGe), epitaxially grown silicon, or another suitable epitaxially grown semiconductor material. P-type dopants may include boron, another suitable element, or a combination thereof.

However, embodiments of the disclosure are not limited thereto. In some other embodiments, the epitaxial structures 138 are n-type doped regions. The epitaxial structures 138 may include epitaxially grown silicon, epitaxially grown silicon carbide (SiC), epitaxially grown germanium, or another suitable epitaxially grown semiconductor material. N-type dopants may include phosphor, arsenic, another suitable element, or a combination thereof.

In some embodiments, the epitaxial structures 138 are doped in-situ during their epitaxial growth. The initial reaction gas mixture for forming the epitaxial structures 138 contains dopants. In some other embodiments, the epitaxial structures 138 are not doped during the growth of the epitaxial structures 138. Instead, after the formation of the epitaxial structures 138, the epitaxial structures 138 are doped in a subsequent process. In some embodiments, the doping is achieved by using an ion implantation process, a plasma immersion ion implantation process, a gas and/or solid source diffusion process, another applicable process, or a combination thereof. In some embodiments, the epitaxial structures 138 are further exposed to one or more annealing processes to activate the dopants. For example, a rapid thermal annealing process is used.

In some embodiments, some of the epitaxial structures 138 are p-type doped, and the other epitaxial structures 138 are n-type doped. A patterned mask may be used to assist in the respective formation of the epitaxial structures 138 that are p-type doped and the epitaxial structures 138 that are n-type doped.

In some embodiments, the formation of the epitaxial structures 138 that involves the thermal processes is performed after the semiconductor layers 102a-102c are replaced with the dielectric nanostructures 306a-306c. Therefore, germanium from the semiconductor layers 102a-102c is prevented from diffusing into the nearby semiconductor nanostructures 104a′-104c′ during the formation of the epitaxial structures 138 since the semiconductor layers 102a-102c have been replaced with the dielectric nanostructures 306a-306c. The semiconductor nanostructures 104a′-104c′ may thus have a low atomic concentration of germanium impurities, enhancing the quality and reliability of the semiconductor nanostructures 104a′-104c′.

As shown in FIG. 3K, a contact etch stop layer 139 and a dielectric layer 140 are formed over the epitaxial structures 138 and the dummy gate stacks 120A and 120B, in accordance with some embodiments. The contact etch stop layer 139 may be made of or include silicon nitride, silicon oxynitride, silicon carbide, carbon-containing silicon nitride, carbon-containing silicon oxynitride, carbon-containing silicon oxide, aluminum oxide, another suitable material, or a combination thereof. The dielectric layer 140 may be made of or include silicon oxide, silicon oxynitride, borosilicate glass (BSG), phosphoric silicate glass (PSG), borophosphosilicate glass (BPSG), fluorinated silicate glass (FSG), low-k material, porous dielectric material, another suitable material, or a combination thereof.

In some embodiments, an etch stop material layer and a dielectric material layer are sequentially deposited over the structure shown in FIG. 3J. The etch stop material layer may be deposited using a CVD process, an ALD process, a PVD process, another applicable process, or a combination thereof. The dielectric material layer may be deposited using an FCVD process, a CVD process, an ALD process, another applicable process, or a combination thereof.

Afterwards, a planarization process is used to partially remove the etch stop material layer and the dielectric material layer. As a result, the remaining portions of the etch stop material layer and the dielectric material layer respectively form the contact etch stop layer 139 and the dielectric layer 140, as shown in FIG. 3K. The planarization process may include a CMP process, a grinding process, an etching process, a dry polishing process, another applicable process, or a combination thereof.

In some embodiments, the hard mask elements 122 and 124 over the dummy gate stacks 120A and 120B are also removed during the planarization process. In some embodiments, after the planarization process, the top surfaces of the contact etch stop layer 139, the dielectric layer 140, and the dummy gate electrodes 118 are substantially level with each other.

Afterwards, as shown in FIGS. 2O and 3L, the dummy gate electrodes 118 are removed to form trenches 142 using one or more etching processes, in accordance with some embodiments. The trenches 142 are surrounded by the dielectric layer 140. The trenches 142 expose the dummy gate dielectric layer 116. During the etching processes used to remove the dummy gate electrodes 118, the protective elements 206′ may shield the underlying isolation structure 115, effectively preserving its height.

As shown in FIGS. 2P and 3M, the dummy gate dielectric layer 116 and the dielectric nanostructures 306a-306c (which function as sacrificial layers) are removed, in accordance with some embodiments. In some embodiments, one or more etching processes are used to remove the dummy gate dielectric layer 116 and the dielectric nanostructures 306a-306c. As a result, recesses 144 are formed, as shown in FIGS. 2P and 3M.

Due to high etching selectivity, the semiconductor nanostructures 104a′-104c′ are slightly (or substantially not) etched. The semiconductor nanostructures 104a′-104c′ suspended over the semiconductor fin 101B may function as the channel structures of transistors. In some other embodiments, the etchant used for removing the dielectric nanostructures 306a-306c also slightly removes the semiconductor nanostructures 104a′-104c′. As a result, the obtained semiconductor nanostructures 104a′-104c′ become thinner after the removal of the dielectric nanostructures 306a-306c. In some embodiments, the inner portion of each of the semiconductor nanostructures 104a′-104c′ is thinner than the edge portions 105a-105c since the edge portions 105a-105c are surrounded by other elements and thus are prevented from being reached and etched by the etchant.

However, embodiments of the disclosure are not limited thereto. Many variations and/or modifications can be made to embodiments of the disclosure. In some embodiments, the inner portion of each of the semiconductor nanostructures 104a′-104c′ is substantially as thick as the edge portions 105a-105c. In some other embodiments, the inner portion of each of the semiconductor nanostructures 104a′-104c′ is slightly thicker than the edge portions 105a-105c.

After the removal of the dielectric nanostructures 306a-306c (which function as sacrificial layers), the recesses 144 are formed. The recesses 144 connect to the trench 142 and surround each of the semiconductor nanostructures 104a′-104c′. As shown in FIG. 3M, even with the formation of recesses 144 between the semiconductor nanostructures 104a′-104c′, the semiconductor nanostructures 104a′-104c′ remain supported by the neighboring elements, including the epitaxial structures 138 and the inner spacers 136. Therefore, after removing the dummy gate stacks 120A and 120B and the dielectric nanostructures 306a-306c, the released semiconductor nanostructures 104a′-104c′ are prevented from falling.

As shown in FIG. 2P, one of the semiconductor nanostructures 104c′ has an upper corner C1 and a lower corner C2. In some embodiments, the upper corner C1 is more rounded than the lower corner C2. As shown in FIG. 2P, one of the semiconductor nanostructures 104b′ has a corner C3. In some embodiments, the upper corner C1 is more rounded than the corner C3.

During the removal of the dielectric nanostructures 306a-306c (which function as sacrificial layers), the inner spacers 136 protect the epitaxial structures 138 from being etched or damaged. The quality and reliability of the semiconductor device structure are improved.

As shown in FIGS. 2Q and 3N, metal gate stacks 156A and 156B are formed to fill the trenches 142, in accordance with some embodiments. The metal gate stacks 156A and 156B further extend into the recesses 144 to wrap around each of the semiconductor nanostructures 104a′-104c′. Each of the metal gate stacks 156A and 156B includes multiple metal gate stack layers. Each of the metal gate stacks 156A and 156B may include a gate dielectric layer 150, a work function layer 152, and a conductive filling 154.

In some embodiments, the formation of the metal gate stacks 156A and 156B involves the deposition of multiple metal gate stack layers over the dielectric layer 140 to fill the trenches 142 and the recesses 144. The metal gate stack layers extend into the recesses 144 to wrap around each of the semiconductor nanostructures 104a′-104c′.

In some embodiments, the gate dielectric layer 150 is made of or includes a dielectric material with high dielectric constant (high-K). The gate dielectric layer 150 may be made of or include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, one or more other suitable high-K materials, or a combination thereof. The gate dielectric layer 150 may be deposited using an ALD process, a CVD process, another applicable process, or a combination thereof.

In some embodiments, before the formation of the gate dielectric layer 150, interfacial layers are formed on the surfaces of the semiconductor nanostructures 104a′-104c′. The interfacial layers are thin layers made of, for example, silicon oxide. In some embodiments, the interfacial layers are formed by applying an oxidizing agent to the surfaces of the semiconductor nanostructures 104a′-104c′. For example, a hydrogen peroxide-containing liquid may be provided or applied to the surfaces of the semiconductor nanostructures 104a′-104c′ so as to form the interfacial layers.

The work function layer 152 may be used to provide the desired work function for transistors to enhance device performance including improved threshold voltage. In some embodiments, the work function layer 152 is used for forming a PMOS device. The work function layer 152 is a p-type work function layer. The p-type work function layer is capable of providing a work function value suitable for the device, such as equal to or greater than about 4.8 eV.

The p-type work function layer may include metal, metal carbide, metal nitride, another suitable material, or a combination thereof. For example, the p-type metal includes tantalum nitride, tungsten nitride, titanium nitride, another suitable material, or a combination thereof.

In some other embodiments, the work function layer 152 is used for forming an NMOS device. The work function layer 152 is an n-type work function layer. The n-type work function layer is capable of providing a work function value suitable for the device, such as equal to or less than about 4.5 eV.

The n-type work function layer may include metal, metal carbide, metal nitride, or a combination thereof. In some embodiments, the n-type work function is an aluminum-containing layer. The aluminum-containing layer may be made of or include TiAlC, TiAlO, TiAlN, another suitable material, or a combination thereof.

The work function layer 152 may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or a combinations thereof. The thickness and/or the compositions of the work function layer 152 may be fine-tuned to adjust the work function level.

The work function layer 152 may be deposited over the gate dielectric layer 150 using an ALD process, a CVD process, a PVD process, an electroplating process, an electrochemical plating process, another applicable process, or a combination thereof.

In some embodiments, a barrier layer is formed before the work function layer 152 to interface the gate dielectric layer 150 with the subsequently formed work function layer 152. The barrier layer may also be used to prevent diffusion between the gate dielectric layer 150 and the subsequently formed work function layer 152. The barrier layer may be made of or include a metal-containing material. The metal-containing material may include titanium nitride, tantalum nitride, another suitable material, or a combination thereof. The barrier layer may be deposited using an ALD process, a CVD process, a PVD process, an electroplating process, an electrochemical plating process, another applicable process, or a combination thereof.

In some embodiments, different portions of the metal gate stacks 156A and 156B are wrapped around semiconductor nanostructures 104a′-104c′ of different devices including PMOS devices and NMOS devices. Different portions of the metal gate stacks 156A and 156B thus have different types of work function layer or different combinations of work functions layers. Multiple deposition processes and multiple patterning processes may be used to selectively form different work function layers at different portions of the metal gate stacks 156A and 156B.

In some embodiments, the conductive fillings 154 are made of or include a metal material. The metal material may include titanium, tungsten, ruthenium, aluminum, copper, cobalt, another suitable material, or a combination thereof. A conductive layer used for forming the conductive filling may be deposited over the work function layer using a CVD process, an ALD process, a PVD process, an electroplating process, an electrochemical plating process, a spin coating process, another applicable process, or a combination thereof.

In some embodiments, a blocking layer is formed over the work function layer 152 before the formation of the conductive layer used for forming the conductive filling. The blocking layer may be used to prevent the subsequently formed conductive layer from diffusing or penetrating into the work function layer. The blocking layer may be made of or include tantalum nitride, titanium nitride, another suitable material, or a combination thereof. The blocking layer may be deposited using an ALD process, a PVD process, an electroplating process, an electrochemical plating process, another applicable process, or a combination thereof.

Afterwards, a planarization process is performed to remove the portions of the metal gate stack layers outside of the trenches 142 and the recesses 144, in accordance with some embodiments. As a result, the remaining portions of the metal gate stack layers form the metal gate stacks 156A and 156B, as shown in FIGS. 2Q and 3M.

In some embodiments, the conductive filling 154 does not extend into the recesses 144 since the recesses 144 are small and have been filled with other elements such as the gate dielectric layer 150 and the work function layer 152. In some embodiments, even if the conductive filling 154 does not extend into the recesses 144 between the semiconductor nanostructures 104a′-104c′, the conductive filling 154 may fill into the trenches 142 above the semiconductor nanostructure 104c′. However, embodiments of the disclosure are not limited thereto. In some other embodiments, a portion of the conductive filling 154 extends into some of the recesses 144, such as the lower recesses 144 with larger space.

As shown in FIG. 2Q, in some embodiments, the protective elements 206′ ensure that the isolation structure 115 maintains sufficient height even if multiple etching processes are performed. This design minimizes the overlapping area between the metal gate stack 156B and the semiconductor fins 101A and 101B, effectively reducing the capacitance between them. Consequently, the performance and reliability of the semiconductor device structure are enhanced.

In some embodiments, the semiconductor layers 102a-102c are replaced with dielectric nanostructures 306a-306c before the formation of the epitaxial structures 138. During the thermal processes for forming the epitaxial structures 138, the semiconductor layers 102a-102c containing germanium had already been removed. Consequently, the diffusion of germanium impurities from the semiconductor layers 102a-102c to the semiconductor nanostructures 104a′-104c′ is significantly reduced or prevented. As a result, the semiconductor nanostructures 104a′-104c′ have a low atomic concentration of germanium impurities, enhancing the quality and reliability of the semiconductor nanostructures 104a′-104c′. The semiconductor nanostructures 104a′-104c′ may have an atomic concentration of germanium impurities that is within a range from about 0% to about 0.01%.

In some embodiments, the semiconductor nanostructures 104a′-104c′ are primarily composed of silicon, giving them high etching selectivity compared to the dielectric nanostructures 306a-306c. As a result, no over-etching or only minimal over-etching is required to remove the dielectric nanostructures 306a-306c and to release the semiconductor nanostructures 104a′-104c′. This significantly reduces the surface roughness of the semiconductor nanostructures 104a′-104c′, which in turn decreases current crowding and surface scattering. As a result, the electrical properties, including carrier mobility, of the semiconductor nanostructures 104a′-104c′ are enhanced.

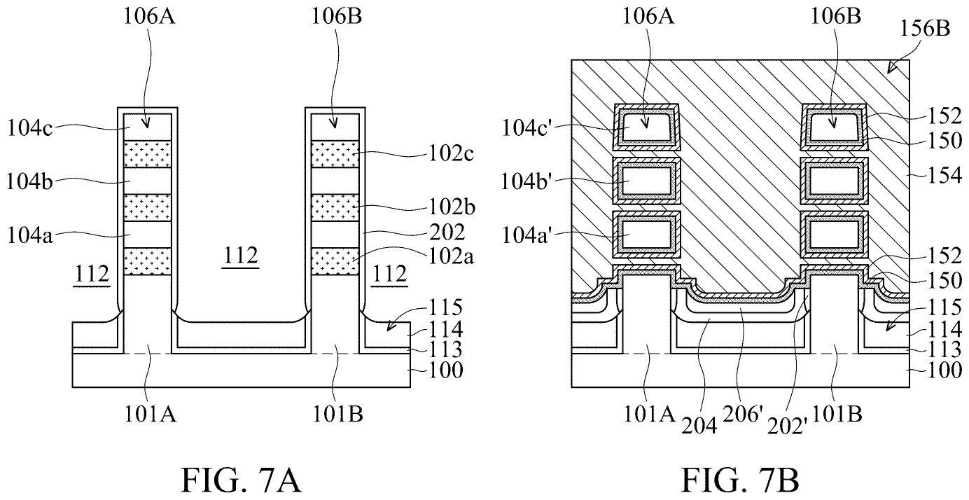

Many variations and/or modifications can be made to embodiments of the disclosure. FIGS. 7A-7B are cross-sectional views of various stages of a process for forming a portion of a semiconductor device structure, in accordance with some embodiments. In some embodiments, a structure that is similar to the structure shown in FIG. 2D is formed. In some embodiments, the cap layer 202 covers the top of the liner layer 113. Afterwards, the processes that are the same as or similar to those shown in FIGS. 2E-2Q are performed. As a result, the structure shown in FIG. 7B is formed, in accordance with some embodiments.

Many variations and/or modifications can be made to embodiments of the disclosure. In some embodiments, there are three channel structures (such as the semiconductor nanostructures 104a′-104c′) formed between the nearby epitaxial structures 138. However, embodiments of the disclosure are not limited thereto. Many variations and/or modifications can be made to embodiments of the disclosure. In some embodiments, the total number of semiconductor nanostructures between the nearby epitaxial structures 138 is greater than three. In some other embodiments, the total number of semiconductor nanostructures between the nearby epitaxial structures 138 is smaller than three. The total number of semiconductor nanostructures (or channel structures) between the nearby epitaxial structures 138 may be fine-tuned to meet requirements. For example, the total number of semiconductor nanostructures between the nearby epitaxial structures 138 may be between 2 and 10. The semiconductor nanostructures may have many applicable profiles. The semiconductor nanostructures may include nanosheets, nanowires, or other suitable nanostructures.

Embodiments of the disclosure form a semiconductor device structure with an isolation structure and a semiconductor fin. The isolation structure surrounds the lower portion of the semiconductor fin. A protective element is formed over the isolation structure. The protective element ensures that the isolation structure maintains sufficient height after multiple etching processes. This design minimizes the overlapping area between the metal gate stack and the semiconductor fin, effectively reducing the capacitance between them. Consequently, the performance and reliability of the semiconductor device structure are enhanced. Due to the protective element, a protruding element may be formed between the protective element and the semiconductor fin.

In accordance with some embodiments, a method for forming a semiconductor device structure is provided. The method includes forming a fin structure over a substrate and forming an isolation structure surrounding a lower portion of the fin structure. The method also includes forming a cap layer extending along a sidewall and a top of the fin structure and forming a mask layer over the cap layer and the isolation structure. The method further includes partially removing the mask layer to partially expose the cap layer. A remaining portion of the mask layer forms a protective element over the isolation structure. In addition, the method includes partially removing the cap layer, and a remaining portion of the cap layer forms a protruding element between the sidewall of the fin structure and the protective element.

In accordance with some embodiments, a method for forming a semiconductor device structure is provided. The method includes forming a fin structure over a substrate. The fin structure has a semiconductor fin and multiple semiconductor nanostructures and multiple semiconductor sacrificial nanostructures laid out in a alternating manner over the semiconductor fin. The method also includes forming an isolation structure surrounding a lower portion of the semiconductor fin and forming a cap layer extending along a sidewall and a top of the fin structure. The method further includes forming a protective element over the isolation structure, and a top of the protective element is vertically between a top of the semiconductor fin and the substrate. In addition, the method includes partially removing the cap layer, and a remaining portion of the cap layer forms a protruding element between the semiconductor fin and the protective element.

In accordance with some embodiments, a semiconductor device structure is provided. The semiconductor device structure includes a semiconductor fin and an isolation structure laterally surrounding a lower portion of the semiconductor fin. A top surface of the isolation structure is non-planar, and the isolation structure has an oxide-based material. The semiconductor device structure also includes a protective element over the isolation structure. The semiconductor device structure further includes a protruding element protruding from a sidewall of the semiconductor fin. The protruding element is between the semiconductor fin and the protective element.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a fin structure over a substrate;
forming an isolation structure surrounding a lower portion of the fin structure;
forming a cap layer extending along a sidewall and a top of the fin structure;
forming a mask layer over the cap layer and the isolation structure;
partially removing the mask layer to partially expose the cap layer, wherein a remaining portion of the mask layer forms a protective element over the isolation structure; and
partially removing the cap layer, wherein a remaining portion of the cap layer forms a protruding element between the sidewall of the fin structure and the protective element.

2. The method for forming a semiconductor device structure as claimed in claim 1, wherein the cap layer is a semiconductor layer epitaxially grown on the fin structure.

3. The method for forming a semiconductor device structure as claimed in claim 1, further comprising:
forming a liner layer over the cap layer before the mask layer is formed.

4. The method for forming a semiconductor device structure as claimed in claim 1, further comprising:
forming an anti-reflection layer covering the mask layer;
removing an upper portion of the anti-reflection layer to expose an upper portion of the mask layer;
removing the upper portion of the mask layer;
removing a remaining portion of the anti-reflection layer to expose the mask layer; and
partially removing the mask layer after the anti-reflection layer is removed such that the protective element is formed.

5. The method for forming a semiconductor device structure as claimed in claim 1, wherein the isolation structure is formed to have a first portion and a second portion, the first portion is beside the fin structure, the first portion is between the second portion and the fin structure, and the first portion is thicker than the second portion.

6. The method for forming a semiconductor device structure as claimed in claim 1, wherein:
the fin structure has a semiconductor fin,
the fin structure has plurality of semiconductor nanostructures and a plurality of semiconductor sacrificial nanostructures over the semiconductor fin, and
the semiconductor nanostructures and the semiconductor sacrificial nanostructures are laid out in an alternating manner.

7. The method for forming a semiconductor device structure as claimed in claim 6, wherein the protruding element is formed to be vertically between a top of the semiconductor fin and a bottom of the semiconductor fin.

8. The method for forming a semiconductor device structure as claimed in claim 6, further comprising:
forming a gate stack partially covering the fin structure;
replacing the semiconductor sacrificial nanostructures with dielectric nanostructures;
forming inner spacers over side edges of the dielectric nanostructures; and
forming an epitaxial structure on side edges of the semiconductor nanostructures and the inner spacers.

9. The method for forming a semiconductor device structure as claimed in claim 8, further comprising:
forming a dielectric layer over the epitaxial structure to surround the gate stack;
removing a gate stack;
removing the dielectric nanostructures; and
forming a metal gate stack wrapped around the semiconductor nanostructures.

10. The method for forming a semiconductor device structure as claimed in claim 9, wherein the protective element is between the isolation structure and the metal gate stack.

11. A method for forming a semiconductor device structure, comprising:
forming a fin structure over a substrate, wherein the fin structure has a semiconductor fin and a plurality of semiconductor nanostructures and a plurality of semiconductor sacrificial nanostructures laid out in a alternating manner over the semiconductor fin;
forming an isolation structure surrounding a lower portion of the semiconductor fin;
forming a cap layer extending along a sidewall and a top of the fin structure;
forming a protective element over the isolation structure, wherein a top of the protective element is vertically between a top of the semiconductor fin and the substrate; and
partially removing the cap layer, wherein a remaining portion of the cap layer forms a protruding element between the semiconductor fin and the protective element.

12. The method for forming a semiconductor device structure as claimed in claim 11, wherein the cap layer is a semiconductor layer epitaxially grown on a sidewall of the fin structure and a top of the fin structure.

13. The method for forming a semiconductor device structure as claimed in claim 11, further comprising:
forming an oxide liner layer over the cap layer and the isolation structure before the protective element is formed.

14. The method for forming a semiconductor device structure as claimed in claim 11, wherein an outermost point the protruding element is formed to be vertically between a top of the protective element and a bottom of the protective element.

15. The method for forming a semiconductor device structure as claimed in claim 11, further comprising:
forming a dummy gate stack partially covering the fin structure, the protective element, and the protruding element;
forming a dielectric layer laterally surrounding the dummy gate stack;
removing the dummy gate stack;
removing the sacrificial nanostructures; and
forming a metal gate stack wrapped around the semiconductor nanostructures and partially covering the protective element and the protruding element.

16. A semiconductor device structure, comprising:
a semiconductor fin;
an isolation structure laterally surrounding a lower portion of the semiconductor fin, wherein a top surface of the isolation structure is non-planar, and the isolation structure has an oxide-based material;
a protective element over the isolation structure; and
a protruding element protruding from a sidewall of the semiconductor fin, wherein the protruding element is between the semiconductor fin and the protective element.

17. The semiconductor device structure as claimed in claim 16, wherein the protruding element and the semiconductor fin are made of a same semiconductor material.

18. The semiconductor device structure as claimed in claim 16, further comprising:
a plurality of semiconductor nanostructures over the semiconductor fin; and
a metal gate stack wrapped around the semiconductor nanostructures and partially covering the protruding element and the protective element.

19. The semiconductor device structure as claimed in claim 16, wherein an outermost point the protruding element is vertically between a top of the protective element and a bottom of the protective element.

20. The semiconductor device structure as claimed in claim 16, wherein the isolation structure has a first portion and a second portion, the first portion is beside the semiconductor fin, the first portion is between the second portion and the semiconductor fin, and the first portion is thicker than the second portion.
